(19) United States
(12) Patent Application Publication
(10) Pub. No.: US 2026/0201741 A1
(43) Pub. Date: Jul. 16, 2026

(54) AUTOMATIC ENTRANCE BARRIER SYSTEM WITH DC MOTOR

(71) Applicant: ASSA ABLOY ENTRANCE SYSTEMS AB, Landskrona (SE)

(72) Inventors: Davide BRAGGION, Milan (IT); Pasquale DI LORENZO, Milan (IT)

(21) Appl. No.: 19/136,658

(22) PCT Filed: Dec. 11, 2023
(86) PCT No.: PCT/EP2023/085126

§ 371 Date: Jun. 6, 2025

(30) Foreign Application Priority Data
Dec. 20, 2022 (SE) 2230435-6

(51) Int. Cl. E05F 15/60; G01R 31/34; H02P 21/14

(52) U.S. Cl. CPC E05F 15/60; G01R 31/343; H02P 21/143; E05Y 2900/106; E05Y 2900/40

(57) ABSTRACT

ASSA ABLOY Entrance Systems AB has developed a method for determining a load on a DC motor (24) of an automatic entrance barrier system comprises the steps of: receiving quadrature values and/or total current values absorbed by the motor (24) and obtained during a test run of the automatic entrance barrier system; determining an average value for the quadrature and/or for the total current absorbed by the motor (24) during a closed loop operation phase (16) of the motor (24); determining, based at least on the respective average value, a load parameter of the automatic entrance barrier system; and outputting a signal based on the determined load parameter or storing the load parameter. Further, a corresponding computer program product, a control unit (26) and a DC motor (24) comprising such control unit (26) are shown.

### TECHNICAL FIELD

The invention relates to the field of automatic entrance barrier systems being operated by a DC motor, in particular for determining a load on such DC motor as well as a corresponding control unit.

### BACKGROUND

Entrance barriers, such as, e.g., slide gates, swing gates or garage doors, are typically operated in an automated manner by means of a DC motor. To ensure that the entrance barrier is correctly operated by the DC motor, an initial installment and calibration needs to be performed, wherein e.g. a running length of the entrance barrier may need to be determined. Such installment and calibration typically requires manual adjustments of parameter values, which is based, to a large extent, on the variety of applications for entrance barriers and their corresponding difference in length and weight.

For example, gates may be provided having a weight from 100 kg to more than 1000 kg and may have a total range up to 20 meters, wherein the entrance barrier may have a length, e.g., between 2.5 meter and 8 meter. Such differences need to be taken into account during installment and calibration.

Furthermore, the implementing conditions may vary, such that upon installment of the automatic entrance barrier system a site-specific slope may be defined for the entrance barrier system, which is preferably taken into account when adjusting the control parameters of the operator, i.e. the DC motor.

### SUMMARY

According to the invention it has been found that the manual adjustments associated with the installation procedure of automatic entrance barrier systems are time consuming and often tedious. Furthermore, it has been found that inputting of incorrect parameter values and/or installment with undersized DC motors may be detrimental for the longevity of the DC motor, potentially requiring an increased maintenance frequency and/or resulting in a loss of functionality of the DC motor.

It is thus an object of the invention to enable an installment that abrogates the above undesirable problems, in particular to provide an easier and faster installment while ensuring long-term compatibility of the DC motor with the entrance barrier.

The object is achieved by a method for determining a load on a DC motor of an automatic entrance barrier system, comprising the steps of:
receiving quadrature values and/or total current values absorbed by the motor and obtained during a test run of the automatic entrance barrier system;
determining an average value for the quadrature and/or for the total current absorbed by the motor during a closed loop operation phase of the motor;
determining, based at least on the respective average value, a load parameter of the automatic entrance barrier system; and
outputting a signal based on the determined load parameter or storing the load parameter.

The quadrature, i.e. I_{q}, corresponds to the current that is typically perpendicular to the magnetic flux and has been found to correspond to the torque created by the motor and being applied to the entrance barrier during operation. In particular, it has been found that the average value may be advantageously associated with the amount of torque that is needed and applied to maintain automated operation of the entrance barrier system and to complete the required run of the entrance barrier.

In other words, such torque may be considered to correspond to a settled torque after an initial torque to overcome the inertia and start movement of the entrance barrier. By means of the average value, the amount of torque that needs to be applied may hence be optimized so as to enable a better performance of the automatic entrance barrier system and/or to provide faster movements of the entrance barrier. Since the total current absorbed by the motor, I_{dc}, follows a similar behavior during closed loop operation, the average value thereof may equally form a measure for the required amount of torque.

The automatic entrance barrier system may be an automatic slide or swing gate, an automatic garage door or an automatic boom barrier, i.e. the entrance barrier being a swing gate, a garage door or a boom barrier, respectively.

Accordingly, the determined respective average value may be advantageously used to perform a calibration and/or a parameter adjustment of the motor, preferably in an automated manner by a control and/or logic unit of the motor.

Hence, the load parameter of the entrance barrier system may be determined without requiring manual input by a user and/or inputting the characteristics of the entrance barrier system. By automatically retrieving such information, installment of the automatic entrance barrier system may be significantly facilitated and accelerated. Furthermore, this renders the installment less error-prone, since inadvertent user errors during manual determining and/or inputting of said load parameter may be effectively avoided.

Preferably, the parameters to be adjusted comprise a run speed, an acceleration, a deceleration, a slowdown limit, an approaching limit, an approaching speed, an obstacle thrust, a starting thrust duration, and/or a disengage.

The determined average value(s), which may be optionally stored, may hence be used to significantly reduce the time required for installment and tuning of the automatic entrance barrier system and may advantageously be used to provide an installment in an automated or semi-automated manner.

The load parameter may be determined by a logic control and/or a motor control of the motor, which may each be provided as respective dedicated microcontrollers and may e.g. be combined on a single electronic board or be provided on separate electronic boards. In order to determine the load parameter, the quadrature values and/or the absorbed total current may be received via a corresponding interface communicatively and/or electrically coupled to the respective microcontroller.

The determining of the load parameter may hence be performed e.g. by an evaluation unit and/or control unit of the motor. Accordingly, the signal may be output as a control signal to be used for actuation of the motor and/or may be stored, e.g., such that the load parameter may be retrieved as a reference value when required. Alternatively, or in addition, the signal may be output as a warning signal or otherwise including an indication of a potential issue that may require attention of the user.

In an embodiment, a minimum quadrature value of the quadrature values at an end of an initial operation phase of the motor is determined, wherein the load parameter is determined based on said minimum quadrature value.

By determining the quadrature at the end of the initial operation phase of the motor, a measure is provided at a time point, wherein the torque is expected to (just) overcome the inertia force and subsequently provide movement of the entrance barrier. Accordingly, the minimum quadrature value advantageously provides a measure of a load parameter of the automatic entrance barrier system in quasi static operation.

Preferably, the initial operation phase includes a maximum quadrature value in the received quadrature values, wherein the minimum quadrature value is the minimum of the received quadrature values received within the initial operation phase after said maximum quadrature value. By determining the minimum quadrature value after such maximum, i.e. after a peak having the largest amplitude or measurement value within said initial operation phase, a correlation of the minimum value with the torque applied to overcome the initial inertia force of the entrance barrier is advantageously increased. In other words, potential quadrature value fluctuations or other factors influencing the quadrature values so as to define local minima and/or maxima, may be effectively excluded.

In order to further ensure that the minimum quadrature value corresponds to the torque being applied just prior to movement of the entrance barrier, the minimum quadrature value is preferably determined at the onset of a subsequent closed loop operation phase of the motor. In particular, said minimum quadrature value may be determined after an initial open loop operation of the motor.

Accordingly, during the test run of the automatic entrance barrier system, a peak current may be obtained for the quadrature, e.g. during open loop control of the motor. Such peak may be obtained since during open loop a current may be applied that has not yet been optimized according to the actually required torque and corresponding current during normal operation, i.e. during movement of the entrance barrier. During a subsequent closed loop, an optimized torque may be applied, which is typically lower than a maximum current obtained during the initial operating phase, such as an open loop control.

In other words, a peak fall of the quadrature may be determined, wherein the minimum quadrature value is preferably determined at a time point after said peak fall and at the onset of subsequent operation with closed loop control. In this manner, the validity of the minimum quadrature value as a load parameter may be further increased while the method is furthermore compatible with a variety of operation and calibration modes requiring, e.g., an initial open loop control.

In addition, this significantly improves safety of operation of the motor, since the load parameter may be determined directly at the beginning of operation. Should the signal indicate a potential problem with the load parameter, e.g. a compatibility issue, a corresponding warning signal may be immediately output and/or further operation of the automatic entrance barrier system may be interrupted until said issue is resolved. Such compatibility is preferably verified prior to installment or calibration of the automatic entrance barrier system, i.e. is preferably verified before actually adjusting the one or more parameters of the automatic entrance barrier system.

Preferably, the load parameter is the weight of the barrier of the automatic entrance barrier system. By determining the weight of the barrier, the installment of the automatic entrance barrier system may be directly optimized based on the actual load on the DC motor. Furthermore, it may be ensured that the performance of the DC motor is compatible with the weight of the entrance barrier, such that an implementation of an undersized DC motor may be avoided.

For example, a DC motor may be designed for an entrance barrier, e.g. a gate, up to 600 kg while it may be inadvertently installed on a gate having a weight of 1000 kg. By the same token, if the gate is installed on a site having an excessive slope, the load or weight may be significantly increased, even if the DC motor is theoretically compatible with the weight of the gate. By determining the weight as a load parameter, such incompatibility may hence be avoided or at least documented. Thereby, the longevity of the automatic entrance barrier system and, in particular, the DC motor may be significantly improved.

The DC motor is preferably a brushless DC motor (“BLDC”) with a stator and rotor and may be configured as a three-phase motor. In accordance, the received quadrature values are preferably determined based on received measurements of a stator current supplied to the motor.

For example, the stator current may be decomposed into two components, the magnetic field generating current, i_{d}, and a torque generating current, i_{q}. Such decomposition process may involve a Clarke-Park transformation and an anti-transformation, wherein the Clarke transformation enables a transition from a three-phase to a static biphasic coordinate system. Assuming, for example, that iₐ is a phase a current, i_{b} is a phase b current, and i_{c} is a phase c current, a new reference system may be given by the static axes α and β according to the Clarke transformation as follows:

$${I}_{α} = \frac{2}{3} {i}_{A} - \frac{1}{3} ( {i}_{B} - {i}_{C} )$$

$${I}_{β} = \frac{2}{\sqrt{3}} ( {i}_{B} - {i}_{C} )$$

The subsequent Park transformation effects the transformation of the static biaxial system defined by the Clark transform (α−β) into a rotating biaxial system (d−q). This transformation allows to shift the vision of the currents from the stator to the rotor, wherein

$$[ \frac{{i}_{d}}{{i}_{q}} ] = [ \begin{matrix}cos {θ}_{R} & sin {θ}_{R} \\ - sin {θ}_{R} & cos {θ}_{R}\end{matrix} ] [ \frac{{i}_{α}}{{i}_{β}} ]$$

and wherein OR represents the position of the rotor.

As described above, I_{q} represents the quadrature, which is perpendicular to the magnetic flux and is considered to correspond to the current providing a torque. I_{d} on the other hand is the so-called direct current, wherein its axis is concordant to the magnetic flux, with a reference value typically being of a magnitude is of zero for permanent magnets. While ignoring I_{d} a direct measure for the applied torque may hence be applied using the measurements of the stator current being supplied to the motor.

Preferably, both the quadrature values and the total current values absorbed by the motor and obtained during the test run are received, wherein the determining of the load and/or the outputting of the signal is based on a difference between the minimum quadrature value and the total current value measured at a time point corresponding to the determined minimum quadrature value.

By receiving the total current absorbed by the motor, the minimum quadrature value may be evaluated in view of the DC-Bus power current, I_{DC}, which may be measured simultaneously with the quadrature values, e.g., via a corresponding interface.

The DC-Bus power current may have a similar course during the initial operating phase compared with the quadrature values and may hence also form a basis to determine the load parameter. In particular, the corresponding minimum value of the total current absorbed by the motor has been found also to follow a preceding maximum or peak value, wherein the minimum value differs depending on the corresponding load parameter value. These differences may be less evident than the corresponding differences for the minimum quadrature values, which is largely due to the relative greater sensitivity of the phase current I_{q} in view of the applied torque. However, by determining a difference between the minimum quadrature value and the (minimum) total current measured at the same time point, the total current absorbed by the motor may be taken into account, such that a correction of the load parameter may be provided. Thereby, the accuracy of the determined load parameter value may be significantly improved.

Alternatively, or in addition, a difference between said values may also form a measure for the validity of the determined load parameter value. For example, should the determined difference indicate that the total current absorbed by the motor is larger than the corresponding minimum quadrature value, an anomaly may be present, e.g. due to an erroneous measurement or a failure in the automatic entrance barrier system. This is because the quadrature value is typically expected to be larger than the total current absorbed by the motor. Should such anomaly be detected, the signal may be accordingly output, e.g. as a warning signal or otherwise indicating a potential error.

The determining of the load parameter may hence, in addition to the determined average value(s) from the closed loop operation phase, take the minimum quadrature value and/or the difference between the minimum quadrature value and an absorbed (minimum) total current for the corresponding time point into account. Thereby, both the accuracy and validity of the determined load parameter and its corresponding value may be further improved. Furthermore, this may provide a level of redundancy. For example, the load parameter may be determined as an average based on the inputted factors.

The load parameter may be determined based on a comparison of the determined value with one or more predefined values corresponding to a respective known value of the load parameter. For example, a determined weight may be compared with a threshold value, which defines a maximum weight limit for a predefined minimum quadrature value. Such predefined minimum quadrature value may previously have been determined using standardized settings for a known weight of an entrance barrier, preferably under standardized conditions. If the minimum quadrature value determined during the test run falls below the predefined minimum quadrature value, it may be considered that the weight of the entrance barrier is within the tolerable limits of the DC motor. However, if said predefined minimum quadrature value is exceeded, the DC motor may be considered undersized and not suitable for the installed entrance barrier.

While a single predefined value may suffice for a particular setup, in an embodiment, a plurality of predefined values may be provided with a respective load value, e.g. a weight. In this manner, a compatibility of the DC motor for a variety of entrance barriers may be assessed while at the same time the actual load of the entrance barrier may be determined with a predefined accuracy. Accordingly, the determined average quadrature may be compared with a series of predefined average quadrature values corresponding to a respective weight and/or torque.

Preferably, each predefined value defines a respective threshold range and/or the comparison is performed iteratively for a plurality of predefined values. By providing a threshold range, measurement inaccuracies and load tolerances may be taken into account and the accuracy of determining the load may be predefined.

The determined value, e.g. the determined average quadrature value, may also be compared in an iterative manner, wherein said determined value is compared with the lowest predefined value or value range and, if said determined value does not correspond to the predefined value or range, a comparison with the next larger value or value range is performed until a matching predefined value with a corresponding load value has been identified. Such iterative process may be based on a look-up table stored in a control unit of the DC motor, wherein an algorithm facilitates that the appropriate value in the look-up table may be identified.

As an example, the determining of the load parameter value may be based on the difference between the minimum quadrature value and the corresponding absorbed total current, wherein the difference may be compared with known difference values for predefined load parameter values. As described above, such known values may have been previously determined and validated under standardized conditions and for known load parameter values. By the same token, the determined difference may hence be compared with one or more thresholds or threshold ranges for corresponding load parameter values, wherein said comparison may be performed using, e.g., a look-up table stored in a control unit of the DC motor and using an iterative algorithm.

Alternatively, a load estimation may also be calculated based on a non-linear function for known loads and corresponding values, e.g. quadrature values. Such non-linear function may e.g. be based on a statistical evaluation of known values under standardized conditions, e.g. using a Pearson coefficient, and/or may be based on machine-learning approaches.

Preferably, respective load parameter values are determined based on the inputted measurement value, i.e. based at least on the respective average value(s) determined for the closed loop operation phase and, optionally, the determined minimum quadrature value and/or the corresponding (minimum) absorbed total current obtained during an initial operation phase of the motor.

Accordingly, a respective load parameter may be determined for each respective determined value and/or a respective load parameter may be determined for an opening phase and a closing phase of the barrier, wherein a signal is preferably output, if one or more respective load parameters differ from each other.

In other words, the respective values of the same load parameter but obtained using a different input value derived from the quadrature value and/or the absorbed total current may be compared and/or matched. This is preferably performed using an algorithm, wherein the hence obtained input value is compared with a corresponding reference value for said load parameter.

By providing respective values for the same load parameter, the validity of the determined load parameter value may be improved. For example, if for each respective input value the same load parameter value is determined, the likelihood of an erroneous calculation is considered negligible due to the present consistency. Thereby, both, operational safety and efficiency of the installment may be increased. In such case, the outputted and/or stored signal may correspond to a single, actual load parameter value.

However, should one or more of the respective load parameters differ from each other, an error or installation issue may be present, such that a signal may be output indicating such potential error or measurement failure.

For example, if the determined load parameter value corresponding to the determined minimum quadrature value is larger than the determined load parameter value corresponding to the determined average of the absorbed total current during the same opening operation phase, this may indicate the presence of an excessive inertia force to start the movement of the entrance barrier. Such difference may e.g. result from an improper mechanical installation. By the same token, if the determined load parameter value based on the minimum quadrature value is smaller, this could indicate the presence of an increased local resistance, e.g. due to soil or pebbles on the running or an irregularity of the entrance barrier. In both cases a signal is output, which may comprise a warning to resolve the indicated problem.

Furthermore, by providing respective load parameter values during opening and closing of the automatic entrance barrier, information regarding a potential slope of the entrance barrier may be derived. For example, if the respective values during opening and closing of the automatic barrier are each matched to a single load parameter value, i.e. a single opening load parameter value and a single closing load parameter value, but said opening value differs from the closing value, this does not automatically result in an invalid of the load parameter value.

For example, in case of a sliding gate this could indicate the presence of a slope. In case the opening parameter value is larger than the closing parameter value, this could indicate that the opening operation is uphill while the closing operation is downhill and vice versa. The outputted signal may include such indication and/or verification.

Preferably, the determined minimum quadrature value or (minimum) difference between the quadrature and the absorbed total current at the end of the initial operation phase, on the one hand, and the respective average values determined during the subsequent closed operation phase, on the other hand, are taken into account to determine the load parameter value of the automatic entrance barrier system. Thereby, the load parameter value may be determined with significant accuracy and high validity.

This may be particularly relevant to determine whether an undersized DC motor has been installed. Accordingly, the determined load parameter is preferably compared with a tolerance limit of the motor, wherein the signal is output based on said comparison.

For example, the tolerance limit may correspond to a compatible maximum weight of the entrance barrier. In case of an undersized DC motor and an exceeding of said limit, this may be detrimental for the DC motor and may cause motor issues, in particular after prolonged operation. Outputting of such signal may prevent that such DC motor is installed in the first place. Alternatively, such signal may assist in resolving a technical issue with an automatic entrance barrier system inadvertently installed with an incompatible motor.

By the same token, such signal may be output, if the determined load parameter value exceeds the tolerance limit, although the provided DC motor is essentially compatible with the entrance barrier to be installed. However, in case of an excessive slope, the DC motor may not be configured to overcome such slope and the corresponding inertia, such that a larger-sized DC motor should be installed in such situation.

On the other hand, an installment and adjustment of parameters or calibration, which may be based on the determined average quadrature and/or average absorbed total current during the closed loop operation phase, may hence advantageously be automatically initiated once it has been verified that the determined load parameter value does not exceed a predefined threshold or tolerance limit of the motor, e.g. a tolerable maximum weight of the entrance barrier.

Accordingly, the invention advantageously provides that currents provided to or derived from the DC motor may be easily measured during operation and be used to, both, efficiently verify the presence of a proper DC motor and expedite or enable the installment of the automatic entrance barrier system in an automated manner.

The determined average value(s) during closed loop operation and/or a determined minimum quadrature value during an initial operation phase may furthermore be monitored over time, wherein the signal comprises a maintenance information based on a monitoring result.

For example, the one or more values that have been determined based on the quadrature measurements and/or the absorbed total current measurements obtained during the test run may be stored and corresponding values may, continuously or periodically, also be obtained during subsequent operation of the automatic entrance barrier system, e.g., during future opening and/or closing maneuvers. This enables that the values may be compared and evaluated, such that the performance of the automatic entrance barrier system may be monitored.

For example, a predefined increase over a predefined period of time may indicate a potential performance degradation compared to the initial performance determined during the test run. The outputted signal may hence comprise a corresponding maintenance information to resolve any potential issues and to optimize the corresponding measurement values to avoid any further damage. In this manner, it is also possible to predict a fault or expected remaining runtime.

Hence, by monitoring the above measurements and determined values, preventive and/or predictive maintenance may also be facilitated so as to avoid malfunctioning of the automatic entrance barrier system and to avoid a sudden stop of the automation due to a malfunction. Thereby, the lifecycle of the automatic entrance barrier system may be significantly improved.

While the method according to the invention may be performed by a separate entity and may e.g. be communicatively coupled to an interface to receive the corresponding measurement values, the method is preferably performed by a control unit of the motor. For example, as described above, the method may be performed by a logic microcontroller and/or control microcontroller of a control unit of the motor.

Furthermore, the above object is achieved by a computer program product, which is embodied on a computer readable storage medium and configured so as when executed on a processor to perform operations of the method according to invention as described above.

The above object is also achieved by a control unit for determining a load on a DC motor of an automatic entrance barrier system, comprising an interface couplable with the DC motor and configured to receive quadrature values and/or total current values absorbed by the motor and obtained during a test run of the automatic entrance barrier system, and an evaluation unit, configured to determine an average value for the quadrature and/or for the total current absorbed by the motor during a closed loop operation phase of the motor and to determine a load parameter of the automatic entrance barrier system based at least on the respective average value. The control unit is configured to output a signal based on the determined load parameter and/or to store the determined load parameter.

In particular, the control unit may be configured to perform the method as described above.

The control unit may e.g. comprise a logic control and a motor control, which may each be configured as dedicated microcontrollers, e.g. on a common electronic board. By means of the interface, measurement values may be received and be evaluated in the evaluation unit, e.g. as part of a logic circuit of the logic control.

Within the control unit or communicatively coupled therewith a storage medium may be provided, which enables that the determined load parameter may be stored and potentially be monitored over time, e.g. for later maintenance retrieval. The outputted signal preferably comprises or is composed as a warning signal in case the determined load parameter value exceeds a predefined threshold value, e.g. a tolerable maximum weight of the entrance barrier. Should the determined load parameter value be within an accepted tolerance range, the signal may indicate proper mechanical installation and/or compatibility. Preferably, the signal may then be used to perform a calibration and/or installation of the automatic entrance barrier system in an automated manner.

Further, the above mentioned object is achieved by a DC motor for an automatic entrance barrier system, comprising the control unit as described above. The DC motor is preferably a brushless DC motor with a stator and rotor and may be configured as a three-phase motor. In accordance, the received quadrature values are preferably determined based on received measurements of a stator current supplied to the motor, e.g. via an interface of the control unit.

The features and advantages discussed with respect to the method also apply to the computer program product, the control unit, and the DC motor and vice versa.

### BRIEF DESCRIPTION OF THE DRAWINGS

The present disclosure will be more readily appreciated by reference to the following detailed description when being considered in connection with the accompanying drawings in which:

FIG. 1: shows a schematic depiction of an automatic entrance barrier system for carrying out a method according to the invention and/or comprising a control unit according to the invention;

FIG. 2: shows a course of quadrature measurement values and absorbed total current values for different operation phases during a test run of a DC motor;

FIG. 3: shows corresponding courses for entrance barrier systems having a different load parameter value;

FIG. 4: shows a table of predefined thresholds for different load parameter values; and

FIG. 5: shows a schematic depiction of a second embodiment of an automatic entrance barrier system for carrying out a method according to the invention and/or comprising a control unit according to the invention.

### DETAILED DESCRIPTION

In the following, the invention will be explained in more detail with reference to the accompanying Figures. In the Figures, like elements are denoted by identical reference numerals and repeated description thereof may be omitted in order to avoid redundancies.

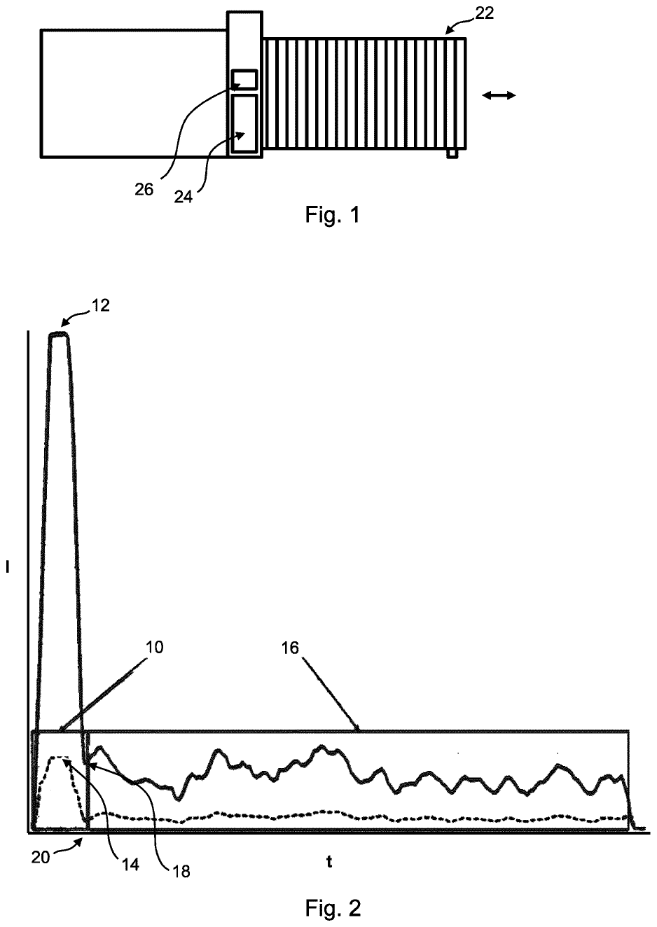

In FIG. 1, an automatic entrance barrier system is schematically depicted in an assembled state. The automatic entrance barrier system comprises an entrance barrier 22, which according to the present example is configured as a slidable gate, as indicated by the double arrowhead. Movement of the entrance barrier 22 during an opening and closing maneuver is provided by a DC motor 24, which is preferably configured as a three-phase motor.

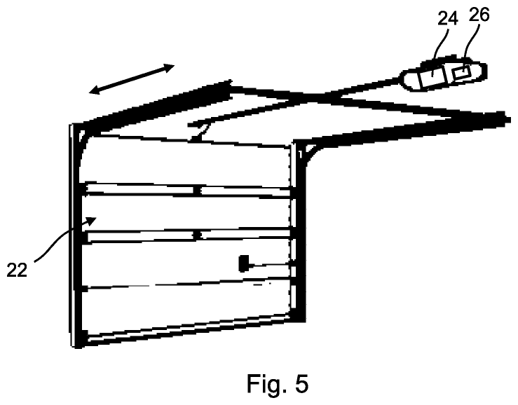

The automatic entrance barrier system may as well be an automatic swing gate, an automatic garage door (FIG. 5) or an automatic boom barrier, i.e. the entrance barrier 22 being a swing gate, a garage door or a boom barrier, respectively.

In order to actuate the DC motor 24, a control unit 26 is provided, which is communicatively coupled to the DC motor 24 and ensures that the required currents are provided to the DC motor 24 so as to initiate and/or complete an opening or closing run of the entrance barrier 22.

The control unit 26 comprises an electronic interface, which allows measurements from the currents provided to the DC motor 24 to be obtained. Said measurements are processed by an evaluation unit of the control unit 26, such that e.g. measurements of quadrature values and/or a total current absorbed by the motor 24 may be received and used to determine a load parameter of the automatic entrance barrier system, e.g. a weight of the slidable gate and/or a settled torque required to complete an opening run of the entrance barrier 22, as described above. By determining said load parameter(s), installment and/or calibration of the automatic entrance barrier system may be facilitated, e.g. by providing corresponding parameter signals to adjust the respective parameter, preferably, also while ensuring compatibility of the implemented DC motor 24 with the installed entrance barrier 22.

In FIG. 2 measurements are depicted for the quadrature (continuous line) and the total current (dashed line) absorbed by the motor, wherein the respective curves indicate the corresponding current value I (A) over time t(s). In the present example, the motor is a brushless DC motor, which has been implemented for opening and closing a gate having a weight of 600 kg and being 1.80 m in length. During operation, the speed of the entrance barrier 22 was set at 10 cm/s and the measurements were obtained during a test run of the automatic entrance barrier system so as to facilitate calibration and/or installation thereof.

During operation, the motor is run in an initial operation phase 10 corresponding to an open loop phase. In said initial operation phase 10 a maximum current is permitted by the motor, such that a corresponding maximum 12 of the quadrature value is obtained. In the present example, said maximum 12 corresponds to about 20 A.

Simultaneously, the total current absorbed by the motor also achieves a respective maximum 14 during the initial operation phase 10. After said initial operation phase 10, i.e. the open loop phase, the control of the motor switches in a closed loop operation phase 16. During the closed loop operation phase 16, the motor control provides an optimal quadrature value, which is based on the actual torque needed to complete the run of the entrance barrier 22, i.e. after the inertia to start movement of the entrance barrier 22 has been overcome.

The respective measurement values during the closed loop operation phase 16 are significantly lower. Accordingly, at the end of the initial operation phase 10, which may essentially coincide with the beginning of the closed loop operation 16, a minimum quadrature value 18 may be determined. For the same time point 20, a corresponding (minimum) value of the total current absorbed by the motor is also present.

As described above, the difference between the minimum quadrature value 18 and the corresponding value of the total current has been found to correlate with the torque needed to overcome the initial inertia of the entrance barrier 22, such that a load parameter value of the automatic entrance barrier system, e.g., the weight of the entrance barrier 22, may be calculated or estimated.

Such difference, rather than a respective absolute value, furthermore has the advantage that a correction for fluctuations or non-linear differences may be taken into account. Furthermore, this provides that the validity of the determined load parameter value may be increased, since the presence of anomalies may be detected, e.g., in case of a determined negative difference value.

After the initial operation phase 10, the motor control switches in closed loop operation, which allows to perform other measurements regarding the motor currents. For the closed loop operation phase 16, which in the present example is about 20 seconds, a respective average value may be determined. Such average value may not only increase the consistency of the determined load parameter value, but may also be used to automate installment of the automatic entrance barrier system by providing adjustments of corresponding parameters.

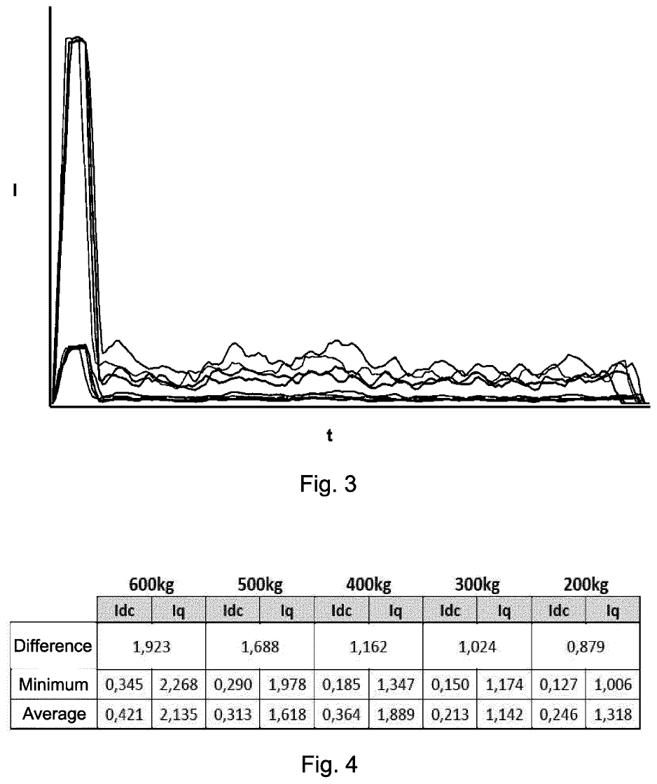

In FIG. 3 corresponding courses are shown for entrance barrier systems having a different load parameter value, which in the present example correspond to different weights. In the Figure, respective curves are depicted for the quadrature values and the total current absorbed by the motor, wherein the curves correspond to weights varying from 200 kg to 600 kg.

As shown, for the top curves, the quadrature values may be well distinguished at the end of the initial operation phase by means of their corresponding minimum quadrature value. By the same token, the corresponding (minimum) value of the total current absorbed by the motor is also distinguishable, yet said differences are less pronounced than the minimum quadrature values. As described above, this may be largely due to the relative greater sensitivity of the phase current I_{q} in view of the applied torque. To correct for potential fluctuations and/or non-linear relationships, the load parameter, e.g. the weight of the entrance barrier 22, may be advantageously determined based on the difference between the minimum quadrature value and the corresponding value of the total current absorbed by the motor.

An example of such differences and corresponding measurement thresholds for different weights as a load parameter is depicted in FIG. 4. Accordingly, measurements have been performed on the motor currents for known weights of the respective entrance barrier 22 and under standardized conditions. Said measurements include the total current absorbed by the motor, depicted as Idc, and the quadrature value, depicted as Iq.

For each current, Idc and Iq, a corresponding minimum value has been determined at the end of an initial operation phase during a test run of the automatic entrance barrier system. As follows from the Figure, despite the linear increase of the weight, the minimum values do not increase linearly. By determining the difference of said minimum values, i.e. Iq−Idc, said non-linear increase is not avoided. However, this enables a clear distinction of the respective thresholds and their corresponding weights.

Furthermore, the average values have been determined during a subsequent closed loop operation of the motor. It can be seen that the average values are not only non-linear with regard to their corresponding weight, but also do not necessarily increase with increasing weight.

It follows that the average value on itself may not be sufficient or not optimal to determine a load parameter value. However, the average value(s) may facilitate adjustment of parameter settings of the automatic entrance barrier system in an automated or semi-automated manner, since the average value is considered to correspond to the amount of torque actually needed to complete an opening or closing run of the entrance barrier 22 after initial movement thereof. Thereby, the average values provide a means for tuning of the corresponding installment parameters, preferably after it has been verified that the maximum tolerable load of the entrance barrier is not exceeded in view of the installed DC motor.

FIG. 5 shows a second embodiment of an automatic entrance barrier system corresponding substantially to the first embodiment. Thus, same and functionally the same components are labeled is with the same reference sign.

The entrance barrier 22 in this embodiment is a garage door which can be opened and closed by the DC motor 24 as indicated by the double arrowhead. The DC motor 24 is controlled by the control unit 26 in the same fashion as described with respect to the first embodiment.

Some of the embodiments contemplated herein are described more fully with reference to the accompanying drawings. Other embodiments, however, are contained within the scope of the subject matter disclosed herein. The disclosed subject matter should not be construed as limited to only the embodiments set forth herein; rather, these embodiments are provided by way of example to convey the scope of the subject matter to those skilled in the art.

The present invention may, of course, be carried out in other ways than those specifically set forth herein without departing from essential characteristics of the invention. The present embodiments are to be considered in all respects as illustrative and not restrictive, and all changes coming within the meaning and equivalency range of the appended claims are intended to be embraced therein.

1. A method for determining a load on a DC motor (24) of an automatic entrance barrier system for a barrier comprising the steps of:
receiving quadrature values and/or total current values absorbed by the motor (24) and obtained during a test run of the automatic entrance barrier system;
determining an average value for the quadrature and/or for the total current absorbed by the motor (24) during a closed loop operation phase (16) of the motor (24);
determining, based at least on the respective average value, a load parameter of the automatic entrance barrier system; and
outputting a signal based on the determined load parameter or storing the load parameter.

2. The method according to claim 1, wherein the respective average value is used to perform a calibration and/or a parameter adjustment of the motor (24), preferably in an automated manner by a control and/or logic unit of the motor (24).

3. The method according to claim 2, wherein the parameters comprise a run speed, an acceleration, a deceleration, a slowdown limit, an approaching limit, an approaching speed, an obstacle thrust, a starting thrust duration, and/or a disengage.

4. The method according to claim 1, wherein the load parameter is the weight of the barrier (22) of the automatic entrance barrier system.

5. The method according to claim 1, wherein the received quadrature values are determined based on received measurements of a stator current supplied to the motor (24).

6. The method according to claim 1, wherein a minimum quadrature value (18) of the quadrature values at an end of an initial operation phase (10) of the motor (24) is determined and wherein the load parameter is determined based on said minimum quadrature value (18).

7. The method according to claim 6, wherein the initial operation phase (10) includes a maximum quadrature value (12) in received quadrature values and wherein the minimum quadrature value (18) is the minimum of the received quadrature values received within the initial operation phase (10) after said maximum quadrature value (12).

8. The method according to claim 6, wherein the minimum quadrature value (18) is determined at the onset of the subsequent closed loop operation phase (16) of the motor (24), preferably after an initial open loop operation of the motor (24).

9. The method according to any of claims 6 to 8, wherein the determining of the load parameter and/or the outputting of the signal is based on a difference between the minimum quadrature value (18) and the total current value measured at a time point (20) corresponding to the determined minimum quadrature value (18).

10. The method according to claim 1, wherein the load parameter is determined based on a comparison of the determined value with one or more corresponding predefined values, each predefined value corresponding to a respective known value of the load parameter.

11. The method according to claim 10, wherein each predefined value defines a respective threshold range and/or wherein the comparison is performed iteratively for a plurality of predefined values.

12. The method according to claim 1, wherein
a respective load parameter is determined for each respective determined value, and/or
a respective load parameter is determined for an opening phase and a closing phase of the barrier, wherein a signal is output, if one or more respective load parameters differ from each other.

13. The method according to claim 1, wherein the determined average value during closed loop operation phase (16) and/or a determined minimum quadrature value (18) are monitored over time and wherein the signal comprises a maintenance information based on a monitoring result.

14. The method according to claim 1, wherein the determined load parameter is compared with a tolerance limit of the motor (24) and the signal is output based on said comparison.

15. The method according to claim 1 being performed by a control unit (26) of the motor (24).

16. A control unit (26) for determining a load on a DC motor (24) of an automatic entrance barrier system comprising
an interface couplable with the DC motor (24) and configured to receive quadrature values and/or total current values absorbed by the motor (24) and obtained during a test run of the automatic entrance barrier system, and
an evaluation unit, configured to determine an average value for the quadrature and/or for the total current absorbed by the motor (24) during a closed loop operation phase (16) of the motor (24) and to determine a load parameter of the automatic entrance barrier system based at least on the respective average value, wherein the control unit (26) is configured to output a signal based on the determined load parameter and/or to store the determined load parameter.

17. The control unit (26) according to claim 16, configured to perform the method according to comprising the steps of:
receiving the quadrature values and/or the total current values absorbed by the motor;
determining the average value for the quadrature and/or for the total current absorbed by the motor during the closed loop operation phase of the motor;
determining, based at least on the respective average value, the load parameter; and
outputting the signal based on the determined load parameter or storing the load parameter.

18. A DC motor (24) for of an automatic entrance barrier system, comprising the control unit (26) according to claim 16.

19. A computer program product, embodied on a computer readable storage medium and configured so as when executed on a processor to perform operations of the method according to claim 1.
